(19) United States
(12) Patent Application Publication
(10) Pub. No.: US 2024/0355798 A1
(43) Pub. Date: Oct. 24, 2024

(54) SEMICONDUCTOR PACKAGE

(71) Applicant: Samsung Electronics Co., Ltd., Suwon-si (KR)

(72) Inventors: Hyeonjeong HWANG, Suwons-si (KR); Kyung Don MUN, Suwon-si (KR); Kyoung Lim SUK, Suwon-si (KR)

(73) Assignee: Samsung Electronics Co., Ltd., Suwon-si (KR)

(21) Appl. No.: 18/500,581

(22) Filed: Nov. 2, 2023

(30) Foreign Application Priority Data
Apr. 19, 2023 (KR) 10-2023-0051500

(51) Int. Cl. H01L 25/16; H01L 23/31; H01L 23/367; H01L 23/498; H10B 80/00

(52) U.S. Cl. CPC H01L 25/16; H01L 23/3121; H01L 23/367; H01L 23/49811; H01L 23/49822; H01L 28/10; H10B 80/00

(57) ABSTRACT

A semiconductor package including a first semiconductor structure on a first redistribution layer structure; first conductive posts on the first redistribution layer structure and next to the first side of the first semiconductor structure; second conductive posts on the first redistribution layer structure and next to a second side opposite to the first side of the first semiconductor structure; a molding material molding the first semiconductor structure, the first conductive posts, and the second conductive posts on the first redistribution layer structure; a second redistribution layer structure on the molding material; a second semiconductor structure on the second redistribution layer structure; a heat dissipation structure on the second redistribution layer structure; and a 3D solenoid inductor including some of the second conductive posts, the redistribution lines at the uppermost of the first redistribution layer structure, and the redistribution lines at the lowermost of the second redistribution layer structure.

### CROSS-REFERENCE TO RELATED APPLICATION

This application claims priority to and the benefit under 35 U.S.C. § 119 to Korean Patent Application No. 10-2023-0051500 filed in the Korean Intellectual Property Office on Apr. 19, 2023, the entire contents of which are incorporated herein by reference.

### BACKGROUND

The present disclosure relates to semiconductor packages.

The semiconductor industry field is seeking to improve an integration density so that more passive or active devices may be integrated in a given region. Among them, as a technology development for miniaturizing a circuit line width of the front end semiconductor process gradually faces limitations, in the semiconductor industry field, a semiconductor package that protects the semiconductor chip on which the integrated circuit is formed is lightweight, thin, down-sized, higher speed and multifunctional, and the semiconductor package with high integration density is developed to supplement the limitations of the front end semiconductor process.

When the semiconductor package is lightweight, thin, down-sized, higher speed and multifunctional, more power is consumed per unit volume of the semiconductor package, which causes a temperature inside the semiconductor package to increase. Particularly, in a package on package (POP), since a molding material and a back-side redistribution layer (BRDL) structure are positioned on a 3D IC (Three Dimensional Integrated Circuit) structure, it becomes difficult to dissipate the heat generated in the 3D integrated circuit (3D IC) structure in an upward direction.

In order to efficiently dissipate the heat generated in the package-on-package (POP) in response to the temperature increasing of the package-on-package (POP), the package on package (POP) may have components that are disposed asymmetrically.

Specifically, the lower package of the package-on-package (POP) may include the three-dimensional integrated circuit (3D IC) structure disposed biasedly from the center of the front-side redistribution layer (FRDL) structure to one side direction, and conductive posts biasedly disposed from the center of the front-side redistribution layer (FRDL) structure to the direction of the other side opposite to one side.

In addition, the upper package of the package on package (POP) may include a memory structure disposed biasedly from the center of the back-side redistribution layer (FRDL) structure to one side direction, and heat slugs that are biasedly disposed from the center of the back-side redistribution layer (BRDL) structure to the direction of the other side opposite to one side.

According to this asymmetric package-on-package (POP), a signal/power may be connected by disposing the memory structure on the conductive posts, and the heat generated in the three-dimensional integration circuit (3D IC) structure may be efficiently dissipated by disposing the heat slug on the three-dimensional integrated circuit (3D IC) structure.

However, in the asymmetric package-on-package (POP), a warpage may occur due to a difference in coefficients of thermal expansions (CTEs) between asymmetrically disposed materials. For example, the part where the conductive posts are positioned has a relatively lower silicon ratio than the part where the three-dimensional integrated circuit (3D IC) structure is positioned, which causes the imbalance of the thermal expansion coefficient (CTE).

As such, if the imbalance of the thermal expansion coefficient (CTE) in the asymmetric package-on-package (POP) is not resolved, the warpage may occur in the semiconductor package, and the operation speed of the semiconductor package may slow down, resulting in problems with a product reliability.

Therefore, it is necessary to develop a new semiconductor package technology capable of improving the imbalance of thermal expansion coefficient (CTE) in the asymmetric package-on-package (POP).

### SUMMARY

In some example embodiments an improved imbalance of thermal expansion coefficient (CTE) may be provided in an asymmetric package-on-package (PoP) according to a semiconductor package in which first conductive posts electrically connecting a front-side redistribution layer structure and a back-side redistribution layer structure are disposed on one side of a three-dimensional integrated circuit (3D IC) structure, second conductive posts are disposed on the other side of the three-dimensional integrated circuit (3D IC) structure, a 3D solenoid inductor formed of the second conductive posts, redistribution lines at the uppermost of the front-side redistribution layer structure, and redistribution lines at the lowermost of the back-side redistribution layer structure.

A semiconductor package according to some example embodiments may include a first redistribution layer structure including first redistribution lines; a first semiconductor structure on the first redistribution layer structure; a plurality of first conductive posts on the first redistribution layer structure and next to a first side of the first semiconductor structure; a plurality of second conductive posts on the first redistribution layer structure and next to a second side opposite to the first side of the first semiconductor structure; a molding material molding the first semiconductor structure, the plurality of first conductive posts, and the plurality of second conductive posts, on the first redistribution layer structure; a second redistribution layer structure including second redistributions lines on the molding material; a second semiconductor structure on the second redistribution layer structure; a heat dissipation structure on the second redistribution layer structure; and a 3D solenoid inductor including, some of the plurality of second conductive posts, the first redistribution lines at an uppermost portion of the first redistribution layer structure, and the second redistribution lines at a lowermost portion of the second redistribution layer structure.

A semiconductor package according to some example embodiments includes a first redistribution layer structure including first redistribution lines; a 3D integrated circuit structure on the first redistribution layer structure and including a first semiconductor die and a second semiconductor die on the first semiconductor die; a plurality of first conductive posts on the first redistribution layer structure and disposed next to a first side of the 3D integrated circuit structure; a plurality of second conductive posts on the first redistribution layer structure and next to a second side opposite to the first side of the 3D integrated circuit structure; a molding material molding the 3D integrated circuit structure, the plurality of first conductive posts, and the plurality of second conductive posts, on the first redistribution layer structure; a second redistribution layer structure including second redistribution lines on the molding material; a semiconductor structure on the second redistribution layer structure; a dummy die on the second redistribution layer structure; and a 3D solenoid inductor including, some of the plurality of second conductive posts, the first redistribution lines at an uppermost portion of the first redistribution layer structure, and the second redistribution lines at a lowermost portion of the second redistribution layer structure.

A semiconductor package according to an embodiment includes a first redistribution layer structure including first redistribution lines; a system on chip (SoC) on the first redistribution layer structure; a plurality of first conductive posts on the first redistribution layer structure and disposed next to a first side of the system on a chip (SoC); a plurality of second conductive posts on the first redistribution layer structure and next to a second side opposite to the first side of the system on a chip (SoC); a first molding material molding the system on chip (SoC), the plurality of first conductive posts, and the plurality of second conductive posts, on the first redistribution layer structure; a second redistribution layer structure including second redistribution lines on the first molding material; a RFIC chip on the second redistribution layer structure; a memory chip on the second redistribution layer structure; a heat slug on the second redistribution layer structure; a second molding material molding the RFIC chip, the memory chip, and the heat slug, on the second redistribution layer structure; and a 3D solenoid inductor including, some of the plurality of second conductive posts, first redistribution lines at an uppermost portion of the first redistribution layer structure, and second redistribution lines at a lowermost portion of the second redistribution layer structure.

An asymmetric package on package (POP) has a merit of efficiently dissipating heat generated in a three-dimensional integrated circuit (3D IC) structure and a drawback of an imbalance of thermal expansion coefficient (CTE), which may cause a warpage.

According to example embodiments, the semiconductor package in which the first conductive posts electrically connecting the front-side redistribution layer structure and the back-side redistribution layer structure are disposed on one side of the three-dimensional integrated circuit (3D IC) structure, the second conductive posts are disposed on the other side of the three-dimensional integrated circuit (3D IC) structure, and the second conductive posts, the redistribution lines at the top of the front-side redistribution layer structure, and the redistribution lines at the bottom of the back-side redistribution layer structure constitute the 3D solenoid inductor may be provided.

As a result, in the asymmetric package on package (POP), while maintaining the merit of efficiently dissipating heat, it may be possible to reduce or prevent the warpage may occur due to the imbalance of the thermal expansion coefficient (CTE).

In addition, in some example embodiments, by constructing the 3D solenoid inductor with the second conductive posts, the redistribution lines at the top of the front-side redistribution layer structure, and the redistribution lines at the bottom of the back-side redistribution layer structure, a Q Factor of the inductor may be improved, a power consumption may be reduced, and a noise may be reduced.

### BRIEF DESCRIPTION OF THE DRAWINGS

FIG. 1 is a cross-sectional view showing some example embodiments of semiconductor packages in which first conductive posts are disposed next to one side of a three-dimensional integrated circuit (3D IC) structure and second conductive posts are disposed next to the other side of the three-dimensional integrated circuit (3D IC) structure, a 3D solenoid inductor is composed of the second conductive posts, second redistribution lines of a front-side redistribution layer structure, and third redistribution vias and third redistribution lines of a back-side redistribution layer structure, and a heat dissipation structure is disposed on the back-side redistribution layer structure.

FIG. 2 is a cross-sectional view of an enlarged 3D solenoid inductor in FIG. 1.

FIG. 3 is a top plan view of a cross-section view of a 3D solenoid inductor shown in FIG. 2 taken along A-A′.

FIG. 4 is a top plan view of a cross-section view of a 3D solenoid inductor shown in FIG. 2 taken along B-B′.

FIG. 5 is a top plan view of a cross-section of a 3D solenoid inductor shown in FIG. 2 taken along C-C′.

FIG. 6 is a perspective view showing a 3D solenoid inductor according to some example embodiments.

FIG. 7 is a cross-sectional view showing some example embodiments of semiconductor packages in which first conductive posts are disposed next to one side of a three-dimensional integrated circuit (3D IC) structure and second conductive posts are disposed next to the other side of the three-dimensional integrated circuit (3D IC) structure, a 3D solenoid inductor is composed of the second conductive posts, second redistribution lines of a front-side redistribution layer structure, and third redistribution vias and third redistribution lines of a back-side redistribution layer structure, and a dummy die is disposed on the back-side redistribution layer structure.

FIG. 8 is a cross-sectional view showing some example embodiments of semiconductor packages in which first conductive posts are disposed next to one side of a three-dimensional integrated circuit (3D IC) structure and second conductive posts are disposed next to the other side of the three-dimensional integrated circuit (3D IC) structure, a 3D solenoid inductor is composed of the second conductive posts, second redistribution lines of a front-side redistribution layer structure, and third redistribution vias and third redistribution lines of a back-side redistribution layer structure, a heat dissipation structure is disposed on the back-side redistribution layer structure, and a memory structure, the heat dissipation structure, and a semiconductor structure are molded on the back-side redistribution layer structure.

FIG. 9 is a cross-sectional view showing some example embodiments of steps of forming a front-side redistribution layer structure on a carrier as one of steps of a method for manufacturing a semiconductor package. FIG. 9 to FIG. 18 are cross-sectional views showing some example embodiments of methods for manufacturing a semiconductor package of FIG. 1. The differences in that FIG. 7 may include a dummy die instead of a heat dissipation structure of FIG. 1, and FIG. 8 further includes a second molding material that molds a memory structure, a heat dissipation structure, and a semiconductor structure, since other features and configurations are the same as the semiconductor package of FIG. 1. The example embodiments of methods of FIG. 9 to FIG. 18 for manufacturing the semiconductor package of FIG. 1 may be applied equally to the method of manufacturing the semiconductor package of FIG. 7 and FIG. 8.

FIG. 10 is a cross-sectional view showing some example embodiments of steps of mounting a first semiconductor die on a front-side redistribution layer structure as one of steps of a method for manufacturing a semiconductor package.

FIG. 11 is a cross-sectional view showing some example embodiments of steps of attaching an insulating member on a first semiconductor die as one of steps of a method for manufacturing a semiconductor package.

FIG. 12 is a cross-sectional view showing some example embodiments of steps of mounting a second semiconductor die on a first semiconductor die as one of steps of a method for manufacturing a semiconductor package.

FIG. 13 is a cross-sectional view showing some example embodiments of steps of forming first conductive posts and second conductive posts on the front-side redistribution layer structure as one of steps of a method for manufacturing a semiconductor package.

FIG. 14 is a cross-sectional view showing some example embodiments of steps of molding a three-dimensional integrated circuit (3D IC) structure, first conductive posts, and second conductive posts on a front-side redistribution layer structure as one of the steps of a method for manufacturing a semiconductor package,

FIG. 15 is a cross-sectional view showing some example embodiments of steps of forming a back-side redistribution layer structure on first conductive posts, second conductive posts, and a first molding material as one of steps of a method for manufacturing a semiconductor package.

FIG. 16 is a cross-sectional view showing some example embodiments of steps of attaching a heat dissipation structure to a back-side redistribution layer structure as one of steps of a method for manufacturing a semiconductor package.

FIG. 17 is a cross-sectional view showing some example embodiments of steps of mounting a memory structure and a semiconductor structure on a back-side redistribution layer structure as one of steps of a method for manufacturing a semiconductor package.

FIG. 18 is a cross-sectional view showing some example embodiments of steps of removing (de-bonding) a carrier from a front-side redistribution layer structure as one of steps of a method for manufacturing a semiconductor package.

### DETAILED DESCRIPTION OF THE EMBODIMENTS

Hereinafter, example embodiments of the present disclosure will be described in detail with reference to the accompanying drawings so that a person of an ordinary skill in the art is enabled to perform the inventive concepts. As those skilled in the art would realize, the described example embodiments may be modified in various different ways, all without departing from the spirit or scope of the present disclosure.

The drawings and description are to be regarded as illustrative in nature and not restrictive. Like reference numerals designate like elements throughout the specification.

Further, since sizes and thicknesses of constituent members shown in the accompanying drawings are arbitrarily given for better understanding and ease of description, the present disclosure is not limited to the illustrated sizes and thicknesses.

Throughout the present specification, when any one part is referred to as being “connected (joined, contacted, and coupled) to” another part, it means that any one part and another part are “directly connected to” each other or are “indirectly connected to” each other with the other part interposed therebetween. In addition, unless explicitly described to the contrary, the word “comprise”, and variations such as “comprises” or “comprising”, will be understood to imply the inclusion of stated elements but not the exclusion of any other elements.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

Further, in the specification, the phrase “on a plane” means when an object portion is viewed from above, and the phrase “on a cross-section” means when a cross-section taken by vertically cutting an object portion is viewed from the side.

Hereinafter, semiconductor packages and semiconductor package manufacturing methods of some example embodiments will be described with reference to drawings.

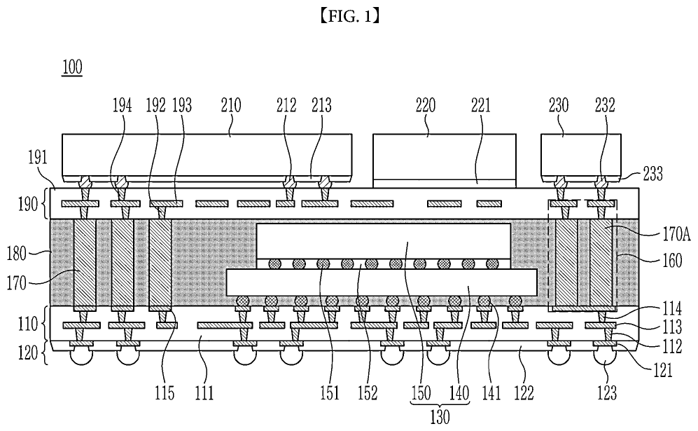

FIG. 1 is a cross-sectional view showing some example embodiments of semiconductor packages in which first conductive posts 170 are disposed next to one side of a three-dimensional integrated circuit (3D IC) structure 130 and second conductive posts 170A are disposed next to the other side of the three-dimensional integrated circuit (3D IC) structure 130, a 3D solenoid inductor 160, and a heat dissipation structure 220 is disposed on the back-side redistribution layer structure 190. A 3D solenoid inductor 160 is composed of the second conductive posts 170A, second redistribution lines 115 of a front-side redistribution layer structure 110, and third redistribution vias 192 and third redistribution lines 193 of a back-side redistribution layer structure 190.

Referring to FIG. 1, a semiconductor package 100 may include the front-side redistribution layer structure 110, an external connecting structure 120, the three-dimensional integrated circuit (3D IC) structure 130 including a first semiconductor die 140 and a second semiconductor die 150, the 3D solenoid inductor 160, the first conductive posts 170, the first molding material 180, the back-side redistribution layer structure 190, a memory structure (a third semiconductor die; 210), the heat dissipation structure 220, and a semiconductor structure 230.

In some example embodiments, the semiconductor package 100 may include a package on package (POP). In some example embodiments, the semiconductor package 100 may include a fan out wafer level package (a fan out wafer level package; FOWLP) or a fan out panel level package (a fan out panel level package; FOPLP).

The front-side redistribution layer structure 110 may include a first dielectric material layer 111, first redistribution vias 112, first redistribution lines 113, second redistribution vias 114, and second redistribution lines 115 disposed in the first dielectric material layer 111. In other example embodiments, the front-side redistribution layer structure 110 including fewer or greater numbers of the redistribution lines and the redistribution vias is included in the scope of the present disclosure.

The first dielectric material layer 111 protects and insulates the first redistribution vias 112, the first redistribution lines 113, the second redistribution vias 114, and the second redistribution lines 115. On the upper surface of the first dielectric material layer 111, the three-dimensional integrated circuit (3D IC) structure 130 including the first semiconductor die 140 and the second semiconductor die 150, the first conductive posts 170, and the second conductive posts 170A may be disposed. The external connecting structure 120 may be disposed on the bottom surface of the first dielectric material layer 111.

The first redistribution via 112 may be disposed between the first redistribution line 113 and the conductive pad 121 of the external connecting structure 120. The first redistribution via 112 may electrically connect the first redistribution line 113 and the conductive pad 121 in a vertical direction. The first redistribution line 113 may be disposed between the first redistribution via 112 and the second redistribution via 114. The first redistribution line 113 may electrically connect the first redistribution via 112 and the second redistribution via 114 in a horizontal direction. The second redistribution via 114 may be disposed between the first redistribution line 113 and the second redistribution line 115. The second redistribution via 114 electrically connect the first redistribution line 113 and the second redistribution line 115 in the vertical direction. The second redistribution line 115 may be disposed between the second redistribution via 114 and the first conductive posts 170, and between the second redistribution via 114 and the second conductive posts 170A. The second redistribution line 115 may electrically connect the second redistribution via 114 and the first conductive posts 170, and the second redistribution via 114 and the second conductive posts 170A in the horizontal direction.

The external connecting structure 120 may be disposed on the bottom surface of the front-side redistribution layer structure 110. The external connecting structure 120 may include conductive pads 121, an insulation layer 122, and external connecting members 123. The conductive pad 121 may electrically connect the first redistribution via 112 of the front-side redistribution layer structure 110 and the external connecting member 123. The insulation layer 122 may include a plurality of openings for a soldering. The insulation layer 122 prevents or reduces in likelihood the external connecting member 123 from being short-circuited. The external connecting member 123 may electrically connect the semiconductor package 100 to an external device.

The three-dimensional integrated circuit (3D IC) structure 130 may be disposed on the upper surface of the front-side redistribution layer structure 110. The three-dimensional integrated circuit (3D IC) structure 130 may include the first semiconductor die 140 and the second semiconductor die 150. In some example embodiments, the three-dimensional integrated circuit (3D IC) structure 130 may include a system on chip (SOC).

The first semiconductor die 140 may be disposed on the upper surface of the front-side redistribution layer structure 110. In some example embodiments, the first semiconductor die 140 may include a central processing unit (CPU) or a graphic processing unit (GPU). The first semiconductor die 140 may include a connection member 141 and may be electrically connected to the second redistribution line 115 of the front-side redistribution layer structure 110 through the connection member 141. In some example embodiments, the connection member 141 may include micro bumps.

In the three-dimensional integrated circuit (3D IC) structure 130 including the first semiconductor die 140 and the second semiconductor die 150 on the first semiconductor die 140, since the second semiconductor die 150 is disposed away from the front-side redistribution layer structure 110 that transmits a signal and a power, a through silicon via (TSV; not shown) may be disposed within the first semiconductor die 140 and is connected to the second semiconductor die 150 to increase the speed at which the second semiconductor die 150 receives and responds to signals and power.

The second semiconductor die 150 may be disposed on the upper surface of the first semiconductor die 140. In some example embodiments, the second semiconductor die 150 may include a communication chip or sensor. The second semiconductor die 150 includes a connection member 151 and may be electrically connected to the first semiconductor die 140 through the connection member 151. In some example embodiments, the connection member 151 may include micro bumps. An insulating member 152 may be disposed between the first semiconductor die 140 and the second semiconductor die 150. The insulating member 152 surrounds and insulates the connection members 151 between the first semiconductor die 140 and the second semiconductor die 150.

Since an inductor occupies a large area in configuring an RFIC chip, and a Q-Factor of the inductor plays an important role in determining an output power and a noise performance, the size and performance of the inductor occupy an important part in the design of the RFIC chip. Therefore, instead of manufacturing the inductor in a back end of line of a Front-End Process of manufacturing the semiconductor chip, if the inductor is manufactured in a back-end process of manufacturing the semiconductor package, the size and performance of the inductor may be improved.

In addition, if the inductor is buried inside the semiconductor chip, a magnetic interference may be induced in a signal/power transmission network having a fine gap formed in the semiconductor chip due to the inductor. Therefore, if the inductor is disposed within the semiconductor package, not inside the semiconductor chip, and the inductor is separated from the signal/power transmission network with a fine gap formed within the semiconductor chip, it is possible to prevent or reduce in likelihood the magnetic interference from being caused to the signal/power transmission network having the fine gap formed in the semiconductor chip.

In addition, in a package on package (POP) formed in an asymmetric structure to efficiently dissipate heat generated in the three-dimensional integrated circuit (3D IC) structure, in order to prevent or reduce in likelihood a warpage caused by the difference in the coefficient of thermal expansions (CTEs) between each asymmetrically disposed material, the 3D solenoid inductor 160 may be disposed on the opposite side of the first conductive posts 170 with the three-dimensional integrated circuit (3D IC) structure 130 interposed therebetween.

In the package on package (POP) formed of an asymmetric structure including the first conductive posts 170 disposed next to one side of the three-dimensional integrated circuit (3D IC) structure 130, the 3D solenoid inductor 160 may be disposed next to the other side opposite to one side of the three-dimensional integrated circuit (3D IC) structure 130 where the first conductive posts 170 are disposed. Thus, by including the 3D solenoid inductor 160 in the semiconductor package 100, it is possible to provide the inductor with improved size and performance, and to prevent or reduce in likelihood the magnetic interference from being caused to the signal/power transmission network having the fine gap formed in the semiconductor chip. In addition, it is possible to prevent or reduce in likelihood the warpage caused by the difference in coefficient of thermal expansion (CTE) between each material.

The first conductive posts 170 may be disposed on the upper surface of the front-side redistribution layer structure 110. The first conductive posts 170 may be disposed next to one side of the three-dimensional integrated circuit (3D IC) structure 130. The first conductive post 170 may be disposed while penetrating the first molding material 180. The side of the first conductive post 170 may be surrounded by the first molding material 180. The first conductive post 170 may electrically connect the second redistribution line 115 of the front-side redistribution layer structure 110 and the third redistribution via 192 of the back-side redistribution layer structure 190. The first conductive post 170 may be electrically connected to the three-dimensional integrated circuit (3D IC) structure 130 through the front-side redistribution layer structure 110.

The second conductive posts 170A may be disposed on the upper surface of the front-side redistribution layer structure 110. The second conductive posts 170A may be disposed next to the other side opposite to one side of the three-dimensional integrated circuit (3D IC) structure 130 in which the first conductive posts 170 are disposed. The second conductive posts 170A may be disposed while penetrating the first molding material 180. The side of the second conductive post 170A may be surrounded by the first molding material 180. The second conductive posts 170A may electrically connect the second redistribution line 115 of the front-side redistribution layer structure 110 and the third redistribution via 192 of the back-side redistribution layer structure 190. The second conductive post 170A may form the 3D solenoid inductor 160. The number of second conductive posts 170A forming the 3D solenoid inductor 160 may be 4 or more. The second conductive post 170A may be electrically insulated from the three-dimensional integrated circuit (3D IC) structure 130. The number of second conductive posts 170A may be less than the number of first conductive posts 170.

The first molding material 180, on the front-side redistribution layer structure 110, may mold the three-dimensional integrated circuit (3D IC) structure 130 including the first semiconductor die 140 and the second semiconductor die 150, the first conductive posts 170, and the second conductive posts 170A.

The back-side redistribution layer structure 190 may be disposed on the first molding material 180. The back-side redistribution layer structure 190 may include a second dielectric material layer 191, and a third redistribution vias 192, a third redistribution lines 193, and a fourth redistribution vias 194 within the second dielectric material layer 191. In other example embodiments, the redistribution layer structure including fewer or greater numbers of redistribution lines and redistribution vias is included in the scope of the present disclosure.

The second dielectric material layer 191 protects and insulates the third redistribution vias 192, the third redistribution lines 193, and the fourth redistribution vias 194. The memory structure 210, the heat dissipation structure 220, and the semiconductor structure 230 may be disposed on the upper surface of the second dielectric material layer 191. The first conductive posts 170, the second conductive posts 170A, and the first molding material 180 may be disposed on the bottom surface of the second dielectric material layer 191.

The third redistribution via 192 may be disposed between the first conductive posts 170 and the third redistribution line 193, between the second conductive posts 170A and the third redistribution line 193. The third redistribution via 192 may electrically connect the first conductive posts 170 and the third redistribution line 193, and the second conductive posts 170A and the third redistribution line 193 in the vertical direction. The third redistribution line 193 may be disposed between the third redistribution via 192 and the fourth redistribution via 194. The third redistribution line 193 may electrically connect the third redistribution via 192 and the fourth redistribution via 194 in the horizontal direction. The fourth redistribution via 194 may be disposed between the third redistribution line 193 and the connection member 212 of the memory structure 210, between the third redistribution line 193 and the adhesion member 221 of the heat dissipation structure 220, and between the third redistribution line 193 and the connection member 232 of the semiconductor structure 230. The fourth redistribution via 194 electrically connect the third redistribution line 193 and the connection member 212 of the memory structure 210, the third redistribution line 193 and the adhesion member 221 of the heat dissipation structure 220, and the third redistribution line 193 and the connection member 232 of the semiconductor structure 230 in the vertical direction.

The memory structure (a third semiconductor die) 210 may be disposed on the back-side redistribution layer structure 190. The memory structure 210 may include a single chip such as DRAM or multiple chips such as high bandwidth memory (HBM). The memory structure 210 may include a connection member 212 and an insulation layer 213. The connection member 212 may electrically connect the memory structure 210 and the back-side redistribution layer structure 190. In some example embodiments, connection member 212 may include a micro bump or a solder ball. The insulation layer 213 may include a plurality of openings for a soldering. The insulation layer 213 prevents or reduces in likelihood the connection member 212 from being short-circuited. In some example embodiments, the insulation layer 213 may include a solder resist.

The heat dissipation structure 220 may be disposed on the back-side redistribution layer structure 190. The heat dissipation structure 220 may include heat slugs. The heat slug may also be referred to as a heat sink or a heat spreader. A region of a footprint of the heat dissipation structure 220 may be included within a region of a footprint of the three-dimensional integrated circuit (3D IC) structure 130. The heat dissipation structure 220 may dissipate heat generated from the three-dimensional integrated circuit (3D IC) structure 130 and improve thermal characteristics of the semiconductor package.

The heat dissipation structure 220 may be adhered on the back-side redistribution layer structure 190 by the adhesion member 221. In some example embodiments, the adhesion member 221 may use a material with excellent heat transfer characteristics. In some example embodiments, the adhesion member 221 may include a thermal interface material (TIM). The thermal interface material (TIM) is a material that is inserted to improve thermal coupling between a device for discharging heat and a heat dissipating device. The thermal interface material (TIM) serves to reduce a thermal contact resistance by filling the air layer of the contact surface between the device for discharging heat and the heat dissipating device.

The semiconductor structure (a fourth semiconductor die) 230 may be disposed on the back-side redistribution layer structure 190. The semiconductor structure 230 may include a semiconductor chip in which the inductor is required. In some example embodiments, the semiconductor structure 230 may include an RFIC chip. The RFIC chip is a chip that transmits and receives a RF signal from an antenna and amplifies it. The semiconductor structure 230 may include a connection member 232 and an insulation layer 233. The connection member 232 may electrically connect the semiconductor structure 230 and the back-side redistribution layer structure 190. In some example embodiments, the connection member 232 may include a micro bump or a solder ball. The insulation layer 233 may include a plurality of openings for the soldering. The insulation layer 233 prevents or reduces in likelihood the connection member 232 from being short-circuited. In some example embodiments, the insulation layer 233 may include a solder resist.

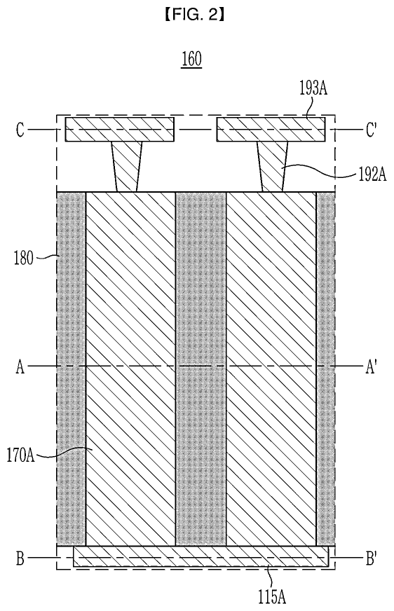

FIG. 2 is a cross-sectional view of an enlarged 3D solenoid inductor 160 in FIG. 1.

Referring to FIG. 2, the 3D solenoid inductor 160 may include a second redistribution line 115A, a second conductive posts 170A, a third redistribution via 192A, and a third redistribution line 193A.

The second redistribution line 115A may be disposed within the first dielectric material layer 111. The upper surface of the second redistribution line 115A may be in contact with the bottom surface of the second conductive posts 170A. The second redistribution line 115A may electrically connect the second conductive posts 170A in the horizontal direction.

The second conductive post 170A may be disposed within the first molding material 180. The bottom surface of the second conductive post 170A may be in contact with the upper surface of the second redistribution line 115A. The upper surface of the second conductive post 170A may be in contact with the bottom surface of the third redistribution via 192A. The second conductive post 170A may electrically connect the second redistribution line 115A and the third redistribution via 192A in the horizontal direction.

The third redistribution via 192A may be disposed within the second dielectric material layer 191. The bottom surface of the third redistribution via 192A may be in contact with the upper surface of the second conductive posts 170A. The third redistribution via 192A may electrically connect the second conductive post 170A and the third redistribution line 193A in a vertical direction.

The third redistribution line 193A may be disposed within the second dielectric material layer 191. The bottom surface of the third redistribution line 193A may be in contact with the upper surface of the third redistribution via 192A. The third redistribution line 193A may electrically connect the third redistribution vias 192A in the horizontal direction.

As such, the 3D solenoid inductor 160 may be implemented with the second redistribution line 115A, the second conductive posts 170A, the third redistribution via 192A, and the third redistribution line 193A. Compared to a 2D spiral inductor, the 3D solenoid inductor 160 has the reduced inductor resistance and the improved inductor Q Factor, so if the 3D solenoid inductor 160 is implemented with the components of the semiconductor package according to the present disclosure, the power consumed by the inductor and the noise generated from the inductor may be reduced.

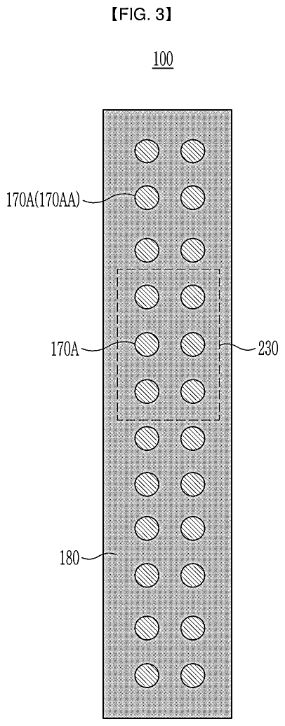

FIG. 3 is a top plan view of a cross-section of a 3D solenoid inductor 160 shown in FIG. 2 taken along A-A′.

Referring to FIG. 3, a second conductive posts 170A may be disposed within the first molding material 180. Since the semiconductor structure 230 is positioned above the line A-A′ in FIG. 2, the outer line of the semiconductor structure 230 is shown as a dotted line. The second conductive posts 170A disposed within the outline of the semiconductor structure 230 may form the 3D solenoid inductor 160 along with the second redistribution line 115A, the third redistribution via 192A, and the third redistribution line 193A. An inductor may be provided to the semiconductor structure 230 by forming the 3D solenoid inductor 160 under the semiconductor structure 230 requiring the inductor. A region of the footprint of the semiconductor structure 230 and a region of the footprint of the 3D solenoid inductor 160 may overlap. The second conductive post 170A disposed outside the outer line of the semiconductor structure 230 may include a dummy post 170AA. The dummy posts 170AA may be electrically insulated from the first redistribution layer structure 110 and the back-side redistribution layer structure 190.

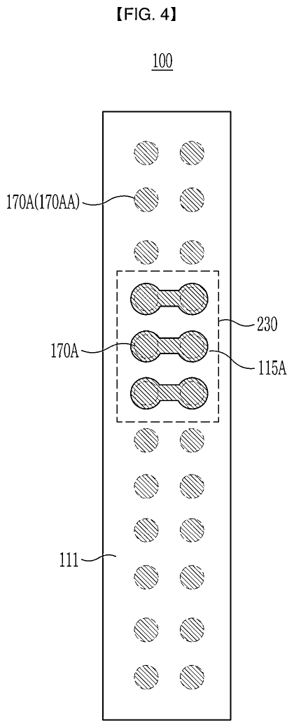

FIG. 4 is a top plan view of a cross-section view of a 3D solenoid inductor 160 shown in FIG. 2 taken along B-B′.

Referring to FIG. 4, a second redistribution lines 115A may be disposed within a first dielectric material layer 111. The second redistribution lines 115A may be in contact with the second conductive posts 170A disposed in the horizontal direction, thereby electrically connecting the second conductive posts 170A disposed in the horizontal direction. Since the semiconductor structure 230 and the second conductive posts 170A are positioned above the line B-B′ in FIG. 2, the outline of the semiconductor structure 230 and the second conductive posts 170A are shown with a dotted line. The second redistribution lines 115A disposed within the outline of the semiconductor structure 230 may form the 3D solenoid inductor 160 together with the second conductive posts 170A, the third redistribution via 192A, and the third redistribution line 193A.

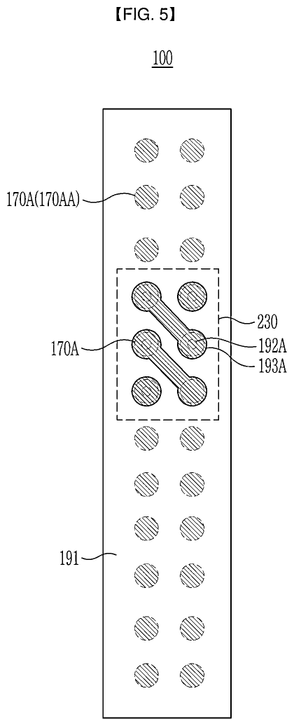

FIG. 5 is a top plan view of a cross-section of a 3D solenoid inductor 160 shown in FIG. 2 taken along C-C′.

Referring to FIG. 5, a third redistribution lines 193A may be disposed within a second dielectric material layer 191. The third redistribution lines 193A may be in contact with the second conductive posts 170A disposed in a diagonal direction and electrically connect the second conductive posts 170A disposed in the diagonal direction. Since the semiconductor structure 230 is positioned above the line C-C′ in FIG. 2, and the second conductive posts 170A and the third redistribution vias 192A are positioned below the line C-C′ in FIG. 2, the outline of the semiconductor structure 230, the second conductive posts 170A, and the third redistribution vias 192A are shown by a dotted line. The third redistribution lines 193A disposed within the outline of the semiconductor structure 230 may form the 3D solenoid inductor 160 together with the second redistribution line 115A, the second conductive posts 170A, and the third redistribution via 192A.

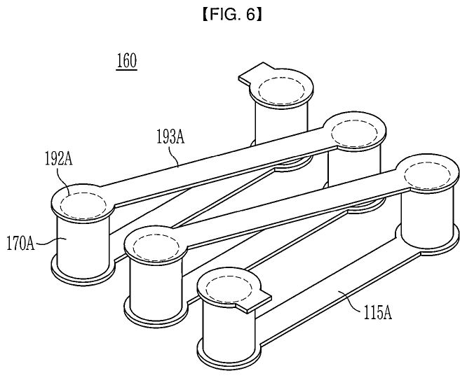

FIG. 6 is a perspective view showing a 3D solenoid inductor 160.

Referring to FIG. 6, the 3D solenoid inductor 160 may have a shape of a solenoid in which a second redistribution line 115A, a second conductive posts 170A, a third redistribution via 192A, and a third redistribution line 193A are sequentially connected. The second redistribution line 115A may be extended in a horizontal direction, thereby electrically connecting the second conductive posts 170A disposed in the horizontal direction. The second conductive post 170A may be extended in the vertical direction to electrically connect the second redistribution line 115A and the third redistribution via 192A. The third redistribution via 192A is covered by the third redistribution line 193A and is shown as a dotted line. The third redistribution via 192A may be extended in the vertical direction to electrically connect the second conductive posts 170A and the third redistribution line 193A. The third redistribution line 193A may be extended in the diagonal direction and electrically connect the second conductive posts 170A disposed in the diagonal direction.

The 3D solenoid inductor 160 may be electrically connected to the semiconductor structure 230 through the back-side redistribution layer structure 190. The 3D solenoid inductor 160 may be electrically insulated from the three-dimensional integrated circuit (3D IC) structure 130.

In the package on package (POP) formed in an asymmetric structure to efficiently dissipate the heat generated in the three-dimensional integrated circuit (3D IC) structure, in order to prevent or reduce in likelihood the warpage caused by the difference in each thermal expansion coefficients (CTE) between the asymmetrically disposed materials, since the 3D solenoid inductor 160 is disposed, there is no limit to the position, size, shape, and number of the second redistribution line 115A, the second conductive posts 170A, the third redistribution via 192A, and the third redistribution line 193A. Therefore, the second redistribution line 115A, the second conductive posts 170A, the third redistribution via 192A, and the third redistribution line 193A that are disposed to various positions, and have various shapes, fewer or more numbers, and various sizes, are included in the range of present disclosure. For example, the cross-section shape of the second conductive posts 170A, and the cross-section shape of the second redistribution line 115A, the third redistribution via 192A, and the third redistribution line 193A at the positioned contacted with the second conductive posts 170A are shown in a circular, however according to other example embodiments, the cross-section shape of the second redistribution line 115A, third redistribution via 192A and third redistribution line 193A may include a polygon. In addition, the third redistribution via 192A may be disposed between the second conductive post 170A and the second redistribution line 115A.

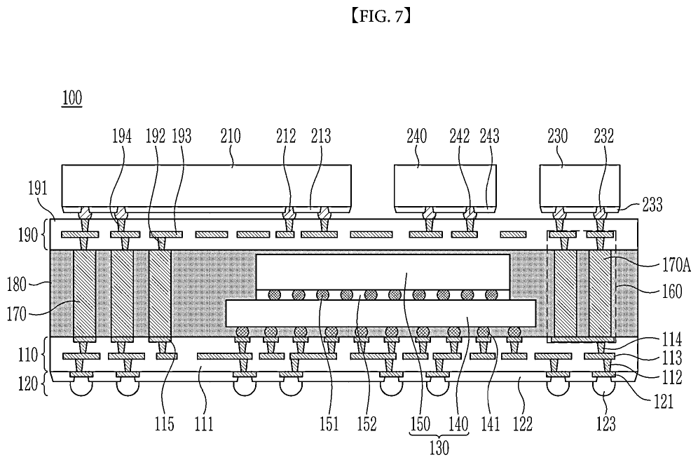

FIG. 7 is a cross-sectional view showing a semiconductor package in which first conductive posts 170 are disposed next to one side of a three-dimensional integrated circuit (3D IC) structure 130 and second conductive posts 170A are disposed next to the other side of the three-dimensional integrated circuit (3D IC) structure 130, a 3D solenoid inductor 160 is composed of the second conductive posts 170A, second redistribution lines 115 of a front-side redistribution layer structure 110, and third redistribution vias 192 and third redistribution lines 193 of a back-side redistribution layer structure 190, and a dummy die 240 is disposed on the back-side redistribution layer structure 190.

In FIG. 1, unlike the heat slug disposed as a heat dissipation structure 220 on the back-side redistribution layer structure 190, referring to FIG. 7, a dummy die 240 may be disposed on the back-side redistribution layer structure 190. The dummy die 240 may enhance heat dissipation characteristics of the semiconductor package by dissipating heat generated in the three-dimensional integrated circuit (3D IC) structure 130 to the outside. In some example embodiments, the dummy die 240 may include at least one of copper, aluminum, gold, silver, iron, stainless steel (SUS) and/or alloys thereof.

The dummy die 240 may include a connection member 242 and an insulation layer 243. The connection member 242 may electrically connect the dummy die 240 and the back-side redistribution layer structure 190. In some example embodiments, the connection member 242 may include a micro bump or solder ball. The insulation layer 243 may include a plurality of openings for a soldering. The insulation layer 243 prevents or reduces in likelihood the connection member 242 from being short-circuited. In some example embodiments, the insulation layer 243 may include a solder resist.

Other features and configurations other than the arrangement of the dummy die 240 on the back-side redistribution layer structure 190 in FIG. 7 are the same as the configurations described in FIG. 1. Accordingly, for the features and configurations other than the arrangement of the dummy die 240 on the back-side redistribution layer structure 190 in FIG. 7, the contents described in FIG. 1 may be equally applied.

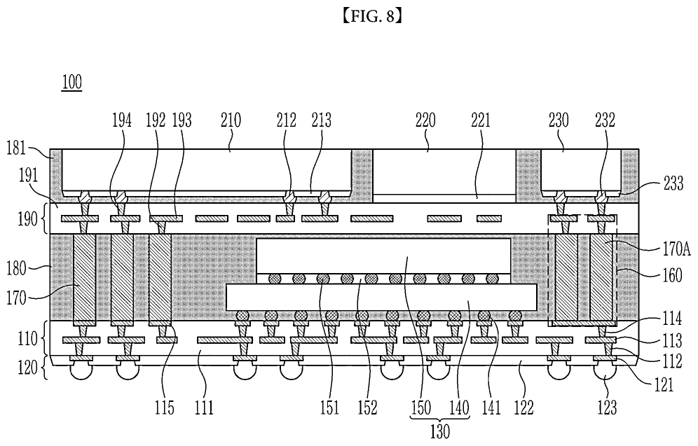

FIG. 8 is a cross-sectional view showing a semiconductor package in which first conductive posts 170 are disposed next to one side of a three-dimensional integrated circuit (3D IC) structure 130 and second conductive posts 170A are disposed next to the other side of the three-dimensional integrated circuit (3D IC) structure 130, a 3D solenoid inductor 160 is composed of the second conductive posts 170A, second redistribution lines 115 of a front-side redistribution layer structure 110, and third redistribution vias 192 and third redistribution lines 193 of a back-side redistribution layer structure 190, a heat dissipation structure 220 is disposed on the back-side redistribution layer structure 190, and a memory structure 210, the heat dissipation structure 220, and a semiconductor structure 230 are molded on the back-side redistribution layer structure 190.

Referring to FIG. 8, the memory structure 210, the heat dissipation structure 220, and the semiconductor structure 230 may be molded on the back-side redistribution layer structure 190 with the second molding material 181. In order to efficiently dissipate the heat generated in the semiconductor package 100, the second molding material 181 may not cover the upper surface of the memory structure 210, the upper surface of the heat dissipation structure 220, and the upper surface of the semiconductor structure 230. Accordingly, the upper surfaces of the memory structure 210, heat dissipation structure 220, and the semiconductor structure 230 may be exposed to the outside.

In FIG. 8, other features and configurations other than molding the memory structure 210, the heat dissipation structure 220, and the semiconductor structure 230 on the back-side redistribution layer structure 190 with the second molding material 181 are the same as the configurations described in FIG. 1. Accordingly, in FIG. 8, for other features and configurations other than molding the memory structure 210, the heat dissipation structure 220, and the semiconductor structure 230 on the back-side redistribution layer structure 190 with the second molding material 181, the contents described in FIG. 1 may be equally applied.

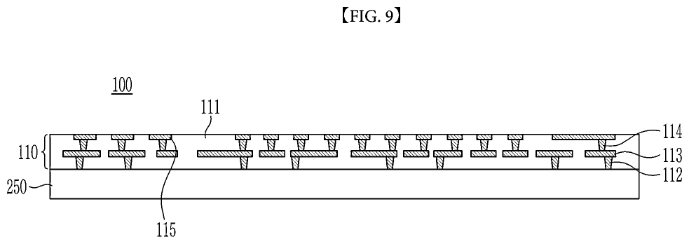

FIG. 9 is a cross-sectional view showing a step of forming a front-side redistribution layer structure 110 on a carrier 250 as one of steps of a method for manufacturing a semiconductor package 100. FIG. 9 to FIG. 18 are cross-sectional views showing example embodiments of methods for manufacturing a semiconductor package 100 of FIG. 1. The differences are in that FIG. 7 includes a dummy die 240 instead of a heat dissipation structure 220 of FIG. 1, and FIG. 8 further includes a second molding material 181 that molds a memory structure 210, a heat dissipation structure 220, and a semiconductor structure 230, since other features and configurations are the same as the semiconductor package 100 of FIG. 1, so that the method of FIG. 9 to FIG. 18 for manufacturing the semiconductor package 100 of FIG. 1 may be applied equally to methods of manufacturing the semiconductor package 100 of FIG. 7 and FIG. 8.

Referring to FIG. 9, a front-side redistribution layer structure 110 is formed on a carrier 250. The carrier 250 may include, for example, a silicon-based material such as glass or silicon oxide, an organic material, or another material such as aluminum oxide, any combination of these materials, and the like.

First, a first dielectric material layer 111 is formed on the carrier 250. In some example embodiments, the first dielectric material layer 111 may include a photosensitive polymer layer. A photosensitive polymer is a material that may form a fine pattern by applying a photolithography process. In some example embodiments, the first dielectric material layer 111 may include a photo imageable dielectric (photosensitive insulator; PID) used in a redistribution layer process. As some example embodiments, the photo imageable dielectric (PID) may include a polyimide-based photosensitive polymer, a novolak-based photosensitive polymer, polybenzoxazole, a silicon (Silicon)-based polymer, an acrylate-based polymer, or an epoxy-based polymer. In other example embodiments, the first dielectric material layer 111 is formed of an inorganic dielectric material such as silicon nitride, silicon oxide, or the like. In some example embodiments, the first dielectric material layer 111 may be formed by a CVD, ALD, or PECVD process.

After forming the first dielectric material layer 111, via holes are formed by selectively etching the first dielectric material layer 111, and first redistribution vias 112 are formed by filling the via holes with a conducting material.

Next, a first dielectric material layer 111 is additionally deposited on the first redistribution vias 112 and the first dielectric material layer 111, the additionally deposited first dielectric material layer 111 is selectively etched to form openings, and the openings are filled with a conducting material to form first redistribution lines 113.

Next, a first dielectric material layer 111 is additionally deposited on the first redistribution lines 113 and the first dielectric material layer 111, and the additionally deposited first dielectric material layer 111 is selectively etched to form via holes, and the via holes are filled with a conducting material to form second redistribution vias 114.

Then, the first dielectric material layer 111 is additionally deposited on the second redistribution vias 114 and the first dielectric material layer 111, the additionally deposited first dielectric material layer 111 is selectively etched to form openings, and the openings are filled with a conducting material to form second redistribution lines 115.

In some example embodiments, the first redistribution vias 112, the first redistribution lines 113, the second redistribution vias 114, and the second redistribution lines 115 may include at least one of copper, aluminum, tungsten, nickel, gold, tin, titanium and/or alloys thereof. In some example embodiments, the first redistribution vias 112, the first redistribution lines 113, the second redistribution vias 114, and the second redistribution lines 115 may be formed by performing a sputtering process. In some example embodiments, the first redistribution vias 112, the first redistribution lines 113, the second redistribution vias 114, and the second redistribution lines 115 may be formed by performing an electrolytic plating process after forming a seed metal layer.

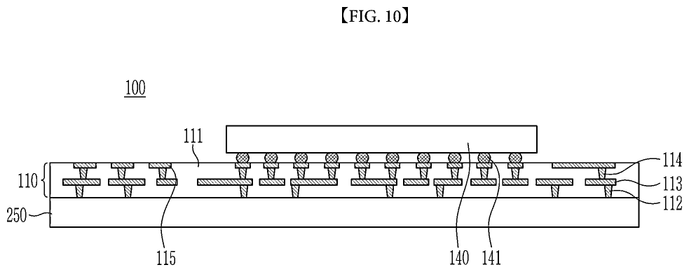

FIG. 10 is a cross-sectional view showing steps of mounting a first semiconductor die 140 on a front-side redistribution layer structure 110 as steps of methods for manufacturing a semiconductor package 100.

Referring to FIG. 10, a first semiconductor die 140 is mounted on the front-side redistribution layer structure 110. The connection member 141 of the first semiconductor die 140 is bonded to the second redistribution line 115 of the front-side redistribution layer structure 110, so that the first semiconductor die 140 and the front-side redistribution layer structure 110 are electrically connected. In some example embodiments, the connection member 141 may include micro bumps.

In the first semiconductor die 140, through-silicon vias (not shown) may be formed. The through-silicon via is formed by forming a hole penetrating the insulating material in the first semiconductor die 140 and filling the hole with a conducting material. In some example embodiments, the hole formed in the first semiconductor die 140 may be formed by a deep etching. In other example embodiments, the hole formed in the first semiconductor die 140 may be formed by a laser. In some example embodiments, the hole formed in the first semiconductor die 140 may be filled with a conducting material by an electrolytic plating. In some example embodiments, the through-silicon via may include at least one of tungsten, aluminum, copper and alloys thereof.

A barrier layer (not shown) may be formed between the through-silicon via and an insulating material of the first semiconductor die 140. In some example embodiments, the barrier layer (not shown) may include at least one of titanium, tantalum, titanium nitride, tantalum nitride and alloys thereof.

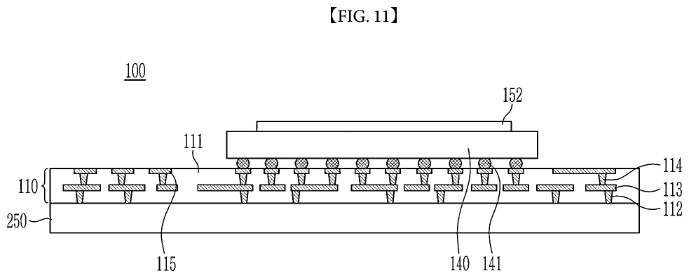

FIG. 11 is a cross-sectional view showing steps of attaching an insulating member 152 on a first semiconductor die 140 as steps of methods for manufacturing a semiconductor package 100.

Referring to FIG. 11, an insulating member 152 is attached on the first semiconductor die 140. In this way, by disposing the insulating member 152, a stress between the first semiconductor die 140 and the second semiconductor die 150 may be relieved. In some example embodiments, the insulating member 152 may include a non-conductive film (NCF).

The non-conductive film (NCF) has adhesiveness and is attached on the first semiconductor die 140. Non-conductive film (NCF) has an uncured state that may be deformed by an external force. The non-conductive film (NCF) may be attached by heating at a temperature of about 170° C. to about 300° C. for about 1 second to about 20 seconds.

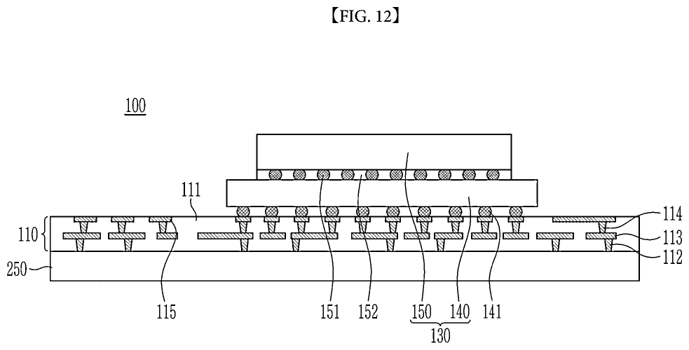

FIG. 12 is a cross-sectional view showing steps of mounting a second semiconductor die 150 on a first semiconductor die 140 as steps of methods for manufacturing a semiconductor package 100.

Referring to FIG. 12, a second semiconductor die 150 is mounted on the first semiconductor die 140. A connection member 151 provided on the second semiconductor die 150 passes through the insulating member 152 and is in contact with the first semiconductor die 140.

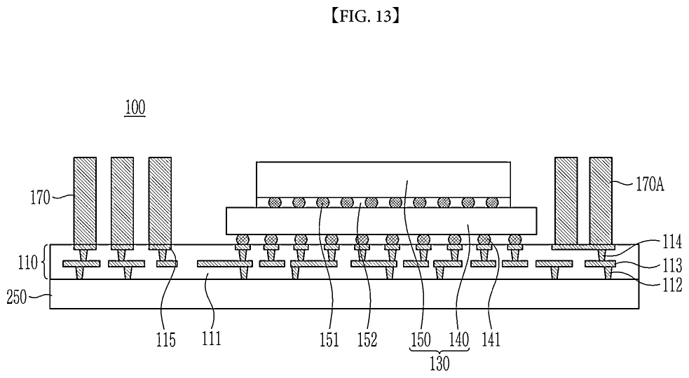

FIG. 13 is a cross-sectional view showing steps of forming first conductive posts 170 and second conductive posts 170A on the front-side redistribution layer structure 110 as steps of methods for manufacturing a semiconductor package 100.

Referring to FIG. 13, the first conductive posts 170 and the second conductive posts 170A are formed on the front-side redistribution layer structure 110. In some example embodiments, the first conductive posts 170 and the second conductive posts 170A may be formed by performing a sputtering process. In other example embodiments, the first conductive posts 170 and the second conductive posts 170A may be formed by performing an electrolytic plating process after forming a seed metal layer. In some example embodiments, the first conductive posts 170 and the second conductive posts 170A may include at least one of copper, aluminum, tungsten, nickel, gold, silver, chromium, antimony, tin, titanium and/or alloys thereof.

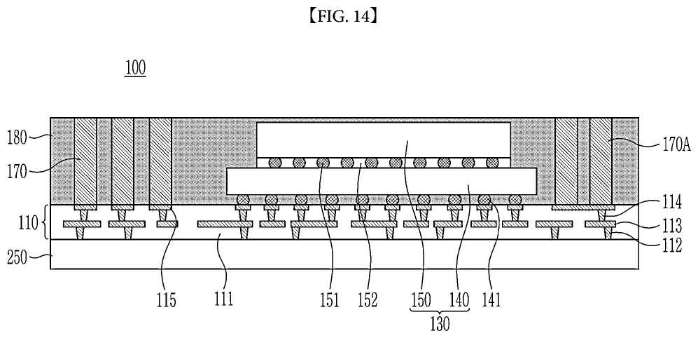

FIG. 14 is a cross-sectional view showing steps of molding a three-dimensional integrated circuit (3D IC) structure 130, first conductive posts 170, and second conductive posts 170A on a front-side redistribution layer structure 110 as steps of methods for manufacturing a semiconductor package 100.

Referring to FIG. 14, on the front-side redistribution layer structure 110, the three-dimensional integrated circuit (3D IC) structure 130, the first conductive posts 170, and the second conductive posts 170A are molded with the first molding material 180. As some example embodiments, the molding process with the first molding material 180 may include a compression molding or transfer molding process. In some example embodiments, the first molding material 180 may be an Epoxy Molding Compound (EMC).

After the molding process, to level the upper surface of the first molding material 180, by performing chemical mechanical polishing (CMP), the upper surface of the first molding material 180 may be planarized.

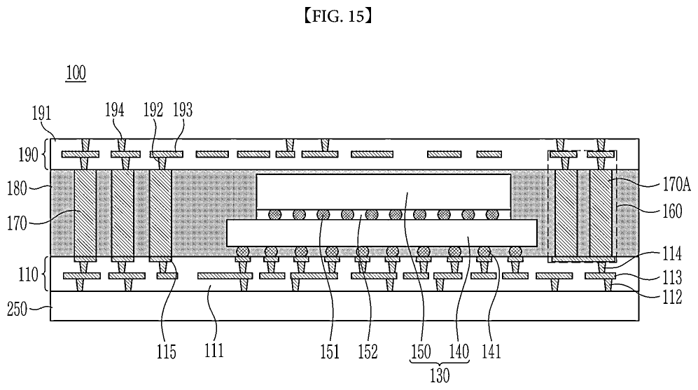

FIG. 15 is a cross-sectional view showing steps of forming a back-side redistribution layer structure on first conductive posts 170, second conductive posts 170A, and a first molding material 180 as one of steps of methods for manufacturing a semiconductor package 100.

Referring to FIG. 15, a back-side redistribution layer structure 190 is formed on the first molding material 180.

First, a second dielectric material layer 191 is formed on the first molding material 180. In some example embodiments, the second dielectric material layer 191 may include a photosensitive polymer layer. The photosensitive polymer is a material that may form fine patterns by applying a photolithography process. In some example embodiments, the second dielectric material layer 191 may include a photo imageable dielectric (PID) used in a redistribution layer process. In some example embodiments, the photo imageable dielectric (PID) may include a polyimide-based photosensitive polymer, a novolak-based photosensitive polymer, polybenzoxazole, a silicon (Silicon)-based polymer, an acrylate-based polymer, or an epoxy-based polymer. In other example embodiments, the second dielectric material layer 191 is formed of an inorganic dielectric material such as silicon nitride, silicon oxide, or the like. In some example embodiments, the second dielectric material layer 191 may be formed with a CVD, ALD, or PECVD process.

After forming the second dielectric material layer 191, via holes are formed by selectively etching the second dielectric material layer 191, and third redistribution vias 192 are formed by filling the via holes with a conducting material.

Then, a second dielectric material layer 191 is additionally deposited on the third redistribution vias 192 and the second dielectric material layer 191, and the additionally deposited second dielectric material layer 191 is selectively etched to form openings, and the openings are filled with a conducting material to form third redistribution lines 193.

Then, a second dielectric material layer 191 is additionally deposited on the third redistribution lines 193 and the second dielectric material layer 191, the additionally deposited second dielectric material layer 191 is selectively etched to form via holes, and the via holes are filled with a conducting material to form fourth redistribution vias 194.

In some example embodiments, the third redistribution vias 192, the third redistribution lines 193, and the fourth redistribution vias 194 may include at least one of copper, aluminum, tungsten, nickel, gold, tin, titanium and alloys thereof. In some example embodiments, the third redistribution vias 192, the third redistribution lines 193, and the fourth redistribution vias 194 may be formed by performing a sputtering process. In some example embodiments, the third redistribution vias 192, the third redistribution lines 193, and the fourth redistribution vias 194 may be formed by performing an electrolytic plating process after forming a seed metal layer.

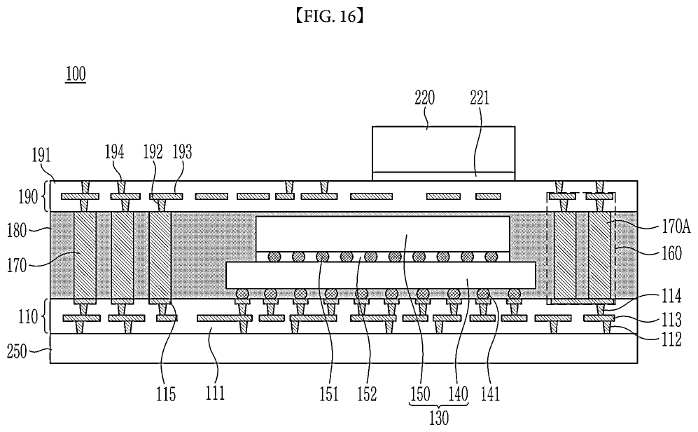

FIG. 16 is a cross-sectional view showing the steps of attaching a heat dissipation structure 220 to a back-side redistribution layer structure 190 as steps of methods for manufacturing a semiconductor package 100.

Referring to FIG. 16, a heat dissipation structure 220 is adhered on the back-side redistribution layer structure 190 by an adhesion member 221. In some example embodiments, the adhesion member 221 may include a thermal interface material (TIM). In some example embodiments, the thermal interface material (TIM) may include a thermal paste, a thermal pad, a phase change material (PCM), or a metal material. In some example embodiments, the thermal interface material (TIM) may include grease.

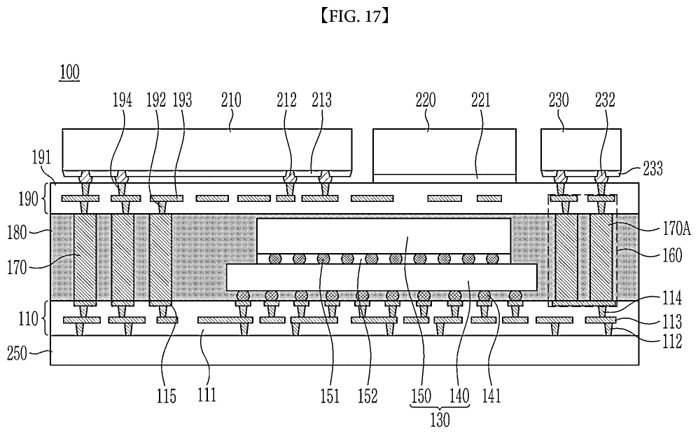

FIG. 17 is a cross-sectional view showing the steps of mounting a memory structure 210 and a semiconductor structure 230 on a back-side redistribution layer structure 190 as steps of methods for manufacturing a semiconductor package 100.

Referring to FIG. 17, the memory structure 210 and the semiconductor structure 230 are mounted on the back-side redistribution layer structure 190. The connection member 212 of the memory structure 210 is bonded to the fourth redistribution via 194 of the back-side redistribution layer structure 190, so that the memory structure 210 and the back-side redistribution layer structure 190 are electrically connected. In some example embodiments, the connection member 212 may include a micro bump or a solder ball. The connection member 232 of the semiconductor structure 230 is bonded to the fourth redistribution via 194 of the back-side redistribution layer structure 190, so that the semiconductor structure 230 and the back-side redistribution layer structure 190 are electrically connected. In some example embodiments, the connection member 232 may include a micro bump or a solder ball.

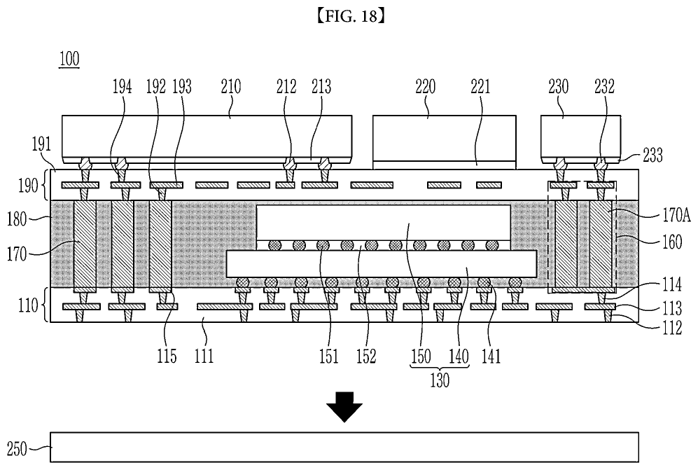

FIG. 18 is a cross-sectional view showing the steps of de-bonding a carrier 250 from a front-side redistribution layer structure 110 as steps of methods for manufacturing a semiconductor package 100.

Referring to FIG. 18, the carrier 250 is removed from the bottom surface of the front-side redistribution layer structure 110.

Subsequently, an external connecting structure 120 is formed on the bottom surface of the front-side redistribution layer structure 110.

While this disclosure has been described in connection with what is presently considered to be practical example embodiments, it is to be understood that the disclosure is not limited to the disclosed example embodiments, but, on the contrary, is intended to cover various modifications and equivalent arrangements included within the spirit and scope of the appended claims.

What is claimed is:

1. A semiconductor package comprising:
a first redistribution layer structure including first redistribution lines;
a first semiconductor structure on the first redistribution layer structure;
a plurality of first conductive posts on the first redistribution layer structure and next to a first side of the first semiconductor structure;
a plurality of second conductive posts on the first redistribution layer structure and next to a second side opposite to the first side of the first semiconductor structure;
a molding material molding the first semiconductor structure, the plurality of first conductive posts, and the plurality of second conductive posts, on the first redistribution layer structure;
a second redistribution layer structure including second redistributions lines on the molding material;
a second semiconductor structure on the second redistribution layer structure;
a heat dissipation structure on the second redistribution layer structure; and
a 3D solenoid inductor including,
some of the plurality of second conductive posts,
the first redistribution lines at an uppermost portion of the first redistribution layer structure, and
the second redistribution lines at a lowermost portion of the second redistribution layer structure.

2. The semiconductor package of claim 1, wherein:
the 3D solenoid inductor is electrically connected to the second semiconductor structure through the second redistribution layer structure.

3. The semiconductor package of claim 1, wherein:
the 3D solenoid inductor is electrically insulated from the first semiconductor structure.

4. The semiconductor package of claim 1, wherein:
the plurality of first conductive posts are electrically connected to the first semiconductor structure through the first redistribution layer structure.

5. The semiconductor package of claim 1, wherein:
some other second conductive posts among the plurality of second conductive posts are dummy posts.

6. The semiconductor package of claim 5, wherein:
the dummy posts are electrically insulated from the first redistribution layer structure and the second redistribution layer structure.

7. The semiconductor package of claim 1, wherein:
a region of a footprint of the second semiconductor structure and a region of a footprint of the 3D solenoid inductor overlap.

8. The semiconductor package of claim 1, wherein:
a region of a footprint of the heat dissipation structure is included within a region of a footprint of the first semiconductor structure.

9. The semiconductor package of claim 1, wherein:
the heat dissipation structure includes a heat slug.

10. The semiconductor package of claim 9, further comprising:
a thermal interface material (TIM) between the heat slug and the second redistribution layer structure.

11. A semiconductor package comprising:
a first redistribution layer structure including first redistribution lines;
a 3D integrated circuit structure on the first redistribution layer structure and including a first semiconductor die and a second semiconductor die on the first semiconductor die;
a plurality of first conductive posts on the first redistribution layer structure and next to a first side of the 3D integrated circuit structure;
a plurality of second conductive posts on the first redistribution layer structure and next to a second side opposite to the first side of the 3D integrated circuit structure;
a molding material molding the 3D integrated circuit structure, the plurality of first conductive posts, and the plurality of second conductive posts, on the first redistribution layer structure;
a second redistribution layer structure including second redistribution lines on the molding material;
a semiconductor structure on the second redistribution layer structure;
a dummy die on the second redistribution layer structure; and
a 3D solenoid inductor including,
some of the plurality of second conductive posts,
the first redistribution lines at an uppermost portion of the first redistribution layer structure, and
the second redistribution lines at a lowermost portion of the second redistribution layer structure.

12. The semiconductor package of claim 11, wherein:
the 3D integrated circuit structure includes a system on chip (SoC).

13. The semiconductor package of claim 11, wherein:
the semiconductor structure includes a RFIC chip.

14. The semiconductor package of claim 11, wherein:
the 3D solenoid inductor further includes redistribution vias at the lowermost portion of the second redistribution layer structure, and
the redistribution vias at the lowermost portion of the second redistribution layer structure are disposed between the second redistribution lines at the lowermost portion of the second redistribution layer structure and some of the plurality of second conductive posts.

15. The semiconductor package of claim 11, wherein:
a number of the plurality of first conductive posts is greater than a number of the plurality of second conductive posts.

16. The semiconductor package of claim 11, wherein:
some of the plurality of second conductive posts included in the 3D solenoid inductor are 4 or more.

17. A semiconductor package comprising:
a first redistribution layer structure including first redistribution lines;
a system on chip (SoC) on the first redistribution layer structure;
a plurality of first conductive posts on the first redistribution layer structure and next to a first side of the system on a chip (SoC);
a plurality of second conductive posts on the first redistribution layer structure and next to a second side opposite to the first side of the system on a chip (SoC);
a first molding material molding the system on chip (SoC), the plurality of first conductive posts, and the plurality of second conductive posts, on the first redistribution layer structure;
a second redistribution layer structure including second redistribution lines on the first molding material;
a RFIC chip on the second redistribution layer structure;
a memory chip on the second redistribution layer structure;
a heat slug on the second redistribution layer structure;
a second molding material molding the RFIC chip, the memory chip, and the heat slug, on the second redistribution layer structure; and
a 3D solenoid inductor including,
some of the plurality of second conductive posts,
first redistribution lines at an uppermost portion of the first redistribution layer structure, and
second redistribution lines at a lowermost portion of the second redistribution layer structure.

18. The semiconductor package of claim 17, wherein:
the memory chip is side by side with the RFIC chip.

19. The semiconductor package of claim 17, wherein:
the heat slug is between the memory chip and the RFIC chip.

20. The semiconductor package of claim 17, wherein:
the semiconductor package includes an asymmetric structure.
